(19) United States
(12) Patent Application Publication
(10) Pub. No.: US 2025/0173950 A1
(43) Pub. Date: May 29, 2025

(54) IMAGE DISPLAY SYSTEM

(71) Applicant: KIDO PACKAGING CORPORATION, Osaka (JP)

(72) Inventor: Seiji KIDO, Osaka (JP)

(21) Appl. No.: 18/839,805

(22) PCT Filed: Feb. 28, 2023
(86) PCT No.: PCT/JP2023/007394

§ 371 Date: Aug. 20, 2024

(30) Foreign Application Priority Data
Mar. 2, 2022 (JP) 2022-032067

(51) Int. Cl. G06T 15/04; G06Q 30/0601

(52) U.S. Cl. CPC G06T 15/04; G06Q 30/0643; G06T 2200/24

(57) ABSTRACT

An object of the present invention is to provide an image display system in which a customer can efficiently arrive at an image of a final product when two-dimensional image data is composited to a container as a commodity. An image display system includes: customer image storage means 3 that stores two-dimensional image data 2 provided by a customer; container data storage means 5 that stores three-dimensional shape data 4 of a container provided by a vendor; stereoscopic image creation means 7 that creates a stereoscopic image 6 by superimposing the two-dimensional image data 2 on the three-dimensional shape data 4; and output means 8 that outputs the stereoscopic image 6 to a display device 9, wherein the two-dimensional image data 2 includes first two-dimensional image data 2A rendered in a single color, and second two-dimensional image data 2B rendered in a plurality of colors.

### TECHNICAL FIELD

The present invention relates to an image display system that creates a stereoscopic image from two-dimensional image data provided by a customer, and three-dimensional shape data of a container provided by a vendor.

### BACKGROUND ART

With recent advances in information technology, people can purchase commodities through mail order, the Internet, etc. In addition, there is known a service in which an image of a commodity for sale and an image possessed by a customer are superimposed on one another on a purchase screen so that the customer can easily understand the final image of the commodity.

For example, Patent Literature 1 discloses a commodity displaying/selling system that is connected to terminals of customers via a network, and includes: image storage means that stores therein information data on the customers; commodity registration means for vendors to register commodities; commodity search means that searches for a commodity requested by a customer from the commodities registered by the commodity registration means; image preparing/compositing means that composites the commodity searched by the commodity search means with an image of the customer prepared from information data inputted through the image input means; output means that outputs the image composited by the image preparing/compositing means to the terminal of the customer; settlement means for settlement of a transaction when the customer purchases the commodity; and a database that stores the information data therein. In this system, the commodity requested by the customer is composited with the image of the customer to form a three-dimensional stereoscopic image, the three-dimensional stereoscopic image is outputted to the terminal of the customer, and the customer can purchase the commodity.

Patent Literature 2 discloses an order-made curtain sales system including at least a customer terminal and a store terminal that can mutually transmit and receive information via a communication network. In this system, the customer terminal includes: a control unit that calculates the size of a curtain, based on image information obtained by photographing an opening part and its vicinity where the curtain is provided; and a transmission/reception unit that transmits, as order information, information on the commodity including the size of the curtain and information on the customer who orders the commodity, to the store terminal via a communication network.

Patent Literature 3 discloses a computer system in which a fitting service providing device including a computer that provides a fitting service and a customer computer equipped with an imaging camera are connected to each other via a network. The fitting service providing device includes: means for storing therein an image of a commodity to be tried on; means for transmitting information on the commodity to be tried on to the customer computer; means for compositing a customer image received from the customer computer with an image of the commodity selected by the customer; and means for transmitting the composite image to the customer computer. The customer computer includes: means for displaying the commodity information received from the fitting service providing device; means for transmitting commodity selection information to the fitting service providing device; means for transmitting a customer image taken by the imaging camera to the fitting service providing device; and means for displaying the composite image of the customer image and the commodity image received from the fitting service providing device.

### CITATION LIST

### Patent Literature

Patent Literature 1: JP-A-2002-063508

Patent Literature 2: JP-A-2007-047946

Patent Literature 3: JP-A-2004-030219

### SUMMARY OF THE INVENTION

### Technical Problem

From the viewpoint of convenience, it is welcome that the customer can grasp the image of the final product by the composite data of the two-dimensional image data provided by the customer and the three-dimensional shape data of the commodity provided by the vendor. However, for example, assuming that a thin wrapping layer is attached to the surface of a container, the color, etc., of the underlying container may be transparently superimposed on the final performance of the composite data. In this case, if the created composite data needs to be corrected, it is difficult to grasp to what extent the composite data, i.e., the image of the final product, will be changed when the color, etc., of the two-dimensional image data to be prepared are changed to a certain extent. As a result, several times of proofing may be required.

An object of the present invention is to provide an image display system in which a customer can efficiently arrive at an image of a final product when two-dimensional image data is composited to a container as a commodity.

### Solutions to the Problems

As a result of thorough research for an image display system suitable for containers, the inventor of the present invention has arrived at an image display system of the below [1]. Image display systems of the below [2] to [12] are more preferable.
[1] An image display system including:

customer image storage means that stores two-dimensional image data provided by a customer;

container data storage means that stores three-dimensional shape data of a container provided by a vendor;

stereoscopic image creation means that creates a stereoscopic image by superimposing the two-dimensional image data on the three-dimensional shape data; and

output means that outputs the stereoscopic image to a display device, wherein

the two-dimensional image data includes first two-dimensional image data rendered in a single color, and second two-dimensional image data rendered in a plurality of colors, and

the stereoscopic image creation means includes
(A) first stereoscopic image creation means that creates a first stereoscopic image by superimposing the first two-dimensional image data on the three-dimensional shape data,
(B) second stereoscopic image creation means that creates a second stereoscopic image by superimposing the second two-dimensional image data on the three-dimensional shape data, and
(C) third stereoscopic image creation means that creates a third stereoscopic image by superimposing the second two-dimensional image data on the first stereoscopic image.
[2] The image display system according to [1], wherein the output means outputs, to the display device, a selection button that allows selection of an image to be displayed on the display device from among the first to third stereoscopic images.
[3] The image display system according to [1] or [2], wherein the output means is capable of displaying a stereoscopic image in which the two-dimensional image data is not superimposed on three-dimensional shape data of a selected container.
[4] The image display system according to any one of [1] to [3], wherein the container is a flexible packaging container.
[5] The image display system according to any one of [1] to [4], further including gloss information imparting means that imparts, to the three-dimensional shape data, information indicating that the container has a glossy surface.
[6] The image display system according to any one of [1] to [5], wherein the first two-dimensional image data is rendered in a single white color.
[7] The image display system according to any one of [1] to [6], wherein the output means is capable of outputting, to the image, a mark indicating a position of a fastener of the container.
[8] The image display system according to any one of [1] to [7], wherein the stereoscopic image creation means further includes fourth stereoscopic image creation means that creates a fourth stereoscopic image by superimposing gloss adjustment data on the third stereoscopic image.
[9] The image display system according to any one of [1] to [8], wherein the two-dimensional image data is data to be printed on a sheet-like material disposed on a surface of the container, the sheet-like material has a first print region having a first side and a second side opposing the first side, and a predetermined warning is issued when at least one of conditions (1) to (3) below is satisfied:
(1) a difference in brightness between the two-dimensional image data in a first edge area including the first side and the two-dimensional image data in a second edge area including the second side is a predetermined value or more;
(2) a difference in chromaticity between the two-dimensional image data in the first edge area including the first side and the two-dimensional image data in the second edge area including the second side is a predetermined value or more; and
(3) a difference in chroma saturation between the two-dimensional image data in the first edge area including the first side and the two-dimensional image data in the second edge area including the second side is a predetermined value or more.
[10] The image display system according to at least one of [1] to [8], wherein the two-dimensional image data is data to be printed on a sheet-like material disposed on a surface of the container, the sheet-like material has a first print region having a first side and a second side opposing the first side, and a second print region having a third side adjacent to the second side of the first print region and a fourth side opposing the third side, and a predetermined warning is issued when at least one of conditions (1) to (3) below is satisfied:
(1) a difference in brightness between the two-dimensional image data in a second edge area including the second side of the first print region and the two-dimensional image data in a third edge area including the third side of the second print region is a predetermined value or more;
(2) a difference in chromaticity between the two-dimensional image data in the second edge area including the second side of the first print region and the two-dimensional image data in the third edge area including the third side of the second print region is a predetermined value or more; and
(3) a difference in chroma saturation between the two-dimensional image data in the second edge area including the second side of the first print region and the two-dimensional image data in the third edge area including the third side of the second print region is a predetermined value or more.
[11] The image display system according to any one of [1] to [10], wherein the container data storage means stores a plurality of three-dimensional shape data, and the image display system further includes container selection means that selects three-dimensional shape data of a container requested by the customer from among the plurality of three-dimensional shape data.
[12] The image display system according to any one of [1] to [11], wherein the customer is capable of settling purchase of a container, based on the first two-dimensional image data and the second two-dimensional image data having been determined.

### Advantageous Effects of the Invention

In the present invention, first two-dimensional image data rendered in a single color and second two-dimensional image data rendered in a plurality of colors are superimposed on data of a container being a commodity, thereby providing a commodity image on which the customer can easily perform proofing.

### BRIEF DESCRIPTION OF THE DRAWINGS

FIG. 1 is a block diagram of an image display system according to an embodiment of the present invention.

FIG. 2 is another block diagram of an image display system according to an embodiment of the present invention.

FIG. 3 is a diagram showing two-dimensional image data and a third stereoscopic image, which are displayed by the image display system according to the embodiment of the present invention.

FIG. 4 is a diagram showing two-dimensional image data and a first stereoscopic image, which are displayed by the image display system according to the embodiment of the present invention.

FIG. 5 is a diagram showing two-dimensional image data and a second stereoscopic image, which are displayed by the image display system according to the embodiment of the present invention.

FIG. 6 is a diagram showing a stereoscopic image in which two-dimensional image data is not superimposed on three-dimensional shape data of a container, which is displayed by the image display system according to the embodiment of the present invention.

FIG. 7 is a diagram showing the stereoscopic image shown in FIG. 6, and a mark indicating the position of a fastener.

FIG. 8 is a diagram showing the stereoscopic image shown in FIG. 3, and a mark indicating the position of a fastener.

FIG. 9 is a plan view of a sheet-like material disposed on the surface of the container.

FIG. 10 is a plan view of a sheet-like material disposed on the surface of the container.

FIG. 11 is a plan view of a sheet-like material disposed on the surface of the container.

FIG. 12 is a plan view of a sheet-like material disposed on the surface of the container.

### DESCRIPTION OF EMBODIMENTS

Embodiments of the present invention will be specifically explained below, however, the present invention is not restricted by the embodiments described below of course, and can be certainly put into practice after appropriate modifications within in a range meeting the gist of the above and the below, all of which are included in the technical scope of the present invention.

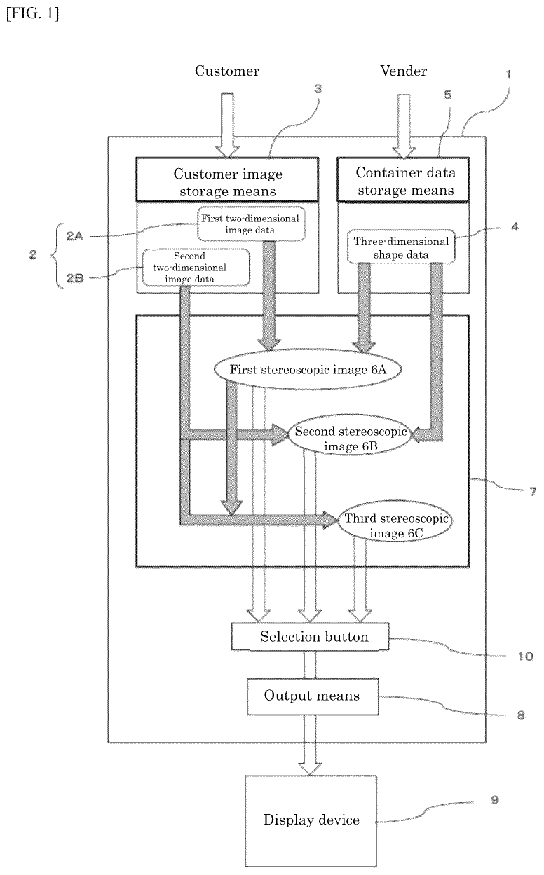

FIG. 1 is a block diagram showing an image display system according to an embodiment of the present invention. As shown in FIG. 1, an image display system 1 includes customer image storage means 3 that stores therein two-dimensional image data 2 provided by a customer, and container data storage means 5 that stores therein three-dimensional shape data 4 of a container provided by a vendor. In addition, the image display system 1 includes stereoscopic image creation means 7 that creates a stereoscopic image 6 by superimposing the two-dimensional image data 2 on the three-dimensional shape data 4. The stereoscopic image 6 is outputted to a display device 9 by the function of output means 8 connected to the stereoscopic image creation means 7.

The two-dimensional image data 2 includes first two-dimensional image data 2A rendered in a single color, and second two-dimensional image data 2B rendered in a plurality of colors. In the embodiment of the present invention, the two-dimensional image data 2 is information on a design applied to the surface of a commodity. It is assumed that the design is formed by multi-coating. The first two-dimensional image data 2A is a base color, and the second two-dimensional image data 2B is a color overwritten on the base color. The details will be described later.

The stereoscopic image creation means 7 includes means (A) to (C) as follows:
(A) first stereoscopic image creation means 7A that creates a first stereoscopic image 6A by superimposing the first two-dimensional image data 2A on the three-dimensional shape data 4;
(B) second stereoscopic image creation means 7B that creates a second stereoscopic image 6B by superimposing the second two-dimensional image data 2B on the three dimensional shape data 4; and
(C) third stereoscopic image creation means 7C that creates a third stereoscopic image 6C by superimposing the second two-dimensional image data 2B on the first stereoscopic image 6A.

In the embodiment of the present invention, a customer is a person who is considering ordering a commodity with his/her own two-dimensional design on the surface of the commodity to be purchased. The two-dimensional image data 2 provided by the customer is electronic data of the two-dimensional design described above.

The two-dimensional image data 2 is prepared on the customer side, and is stored in the customer image storage means 3 of the image display system 1. Any device may be used as the customer image storage means 3 as long as the device can store electronic data therein. For example, a storage device capable of electrically or magnetically storing information may be used. A flash memory, hard disk, magnetic disk, magnetic tape, ROM, etc., may be preferably used. The customer image storage means 3 may be a storage device housed in a personal computer, or may be a storage device existing on a cloud to which the personal computer is connectable through a router.

In the embodiment of the present invention, a vendor is a person who sells a container to the customer. The three-dimensional shape data 4 of the container provided by the vendor is data specifying at least the surface shape of the container. This data may not necessarily specify the entirety of the surface shape of the container, and may specify at least a part of the surface shape of the container. The three-dimensional shape data 4 of the container basically has a three-dimensional data space. However, when a part of the surface shape of the container is flat as described above, valid data in the three-dimensional shape data 4 is two-dimensional data, and zero or the like may be entered as the three-dimensional component.

In the embodiment of the present invention, a container is an object for containing an article inside. However, the container may not necessarily seal the article completely, and may be partially open. Also, the container may not necessarily contain the entirety of the article. The article may be partially exposed without being covered by the container.

The container data storage means 5 is a stretch device that stores therein the three-dimensional shape data 4 of the container provided by the vendor. Like the customer image storage means 3, the container data storage means 5 may be a storage device capable of electrically or magnetically storing information therein.

The two-dimensional image data 2 will be described in more detail. The two-dimensional image data 2 includes the first two-dimensional image data 2A rendered in a single color, and the second two-dimensional image data 2B rendered in a plurality of colors. The “single color” of the first two-dimensional image data 2A is a color that does not change within a two-dimensional plane, such as solid white, solid black, or solid blue. Meanwhile, the second two-dimensional image data 2B is a design that is rendered within a two-dimensional plane by using two or more colors. The design also includes characters. The first two-dimensional image data 2A and the second two-dimensional image data 2B may include transparent color portions.

As shown in FIG. 1, the stereoscopic image creation means 7 creates three types of stereoscopic images 6 (first stereoscopic image 6A, second stereoscopic image 6B, and third stereoscopic image 6C) based on the first two-dimensional image data 2A and/or the second two-dimensional image data 2B. Specifically, the stereoscopic image creation means 7 has the following creation steps (a) to (c).
(a) Creating a first stereoscopic image 6A by superimposing the first two-dimensional image data 2A on the three-dimensional shape data 4.
(b) Creating a second stereoscopic image 6B by superimposing the second two-dimensional image data 2B on the three-dimensional shape data 4.
(c) Creating a third stereoscopic image 6C by superimposing the second two-dimensional image data 2B on the first stereoscopic image 6A.

In the embodiment of the present invention, for example, “superimposing Y data on X data” is a general phrase for a calculation procedure of overlaying a color represented by the Y data on a color represented by the X data. For example, the Y data can be added to and/or integrated with the X data, but the result is not limited to a simple sum and a simple product, and weighted addition and/or integration can be performed. For example, when red is overlaid on white, a resultant color may be pink that is a simple sum. Also, reddish pink or perfect red can be set as a resultant color by increasing the weight of red that is overlaid on white, Alternatively, a transparent color may be overlaid on white to obtain white as a resultant color.

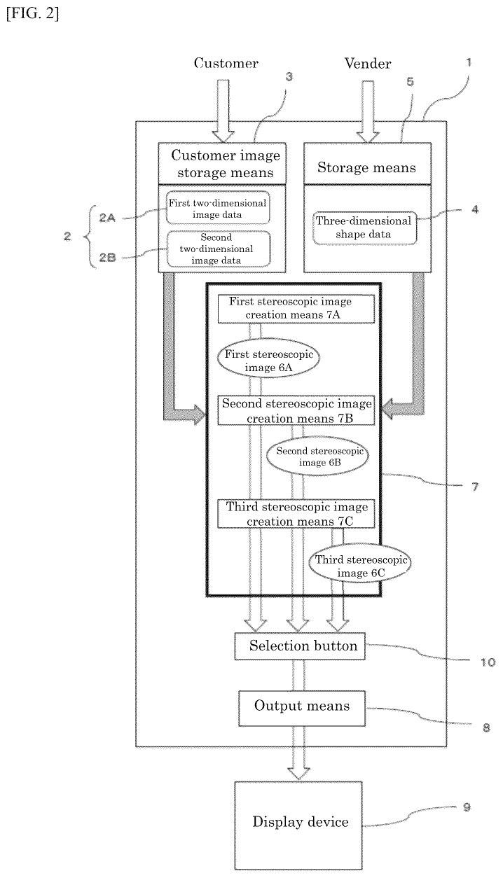

In the example shown in FIG. 1, the stereoscopic image creation means 7 corresponding to the above (c) is described as means that creates the third stereoscopic image 6C by superimposing the second two-dimensional image data 2B on the first stereoscopic image 6A, but the stereoscopic image creation means 7 is not limited to creating the third stereoscopic image 6C through creation of the first stereoscopic image 6A as described above. Even without going through the process of creating the first stereoscopic image 6A, the stereoscopic image creation means 7 may create the third stereoscopic image 6C as a result by using the three-dimensional shape data 4, the first two-dimensional image data 2A, and the second two-dimensional image data 2B. In this regard, FIG. 1 can be displayed more generally as FIG. 2.

FIG. 2 is another block diagram showing the image display system according to the embodiment of the present invention, and more generally describes the functions of the stereoscopic image creation means 7 shown in FIG. 1. As shown in FIG. 2, the stereoscopic image creation means 7, as a whole, receives the first two-dimensional image data 2A, the second two-dimensional image data 2B, and the three-dimensional shape data 4 of the container, and outputs the first stereoscopic image 6A, the second stereoscopic image 6B, and the third stereoscopic image 6C. The first stereoscopic image 6A is created by the function of the first stereoscopic image creation means 7A, the second stereoscopic image 6B is created by the function of the second stereoscopic image creation means 7B, and the third stereoscopic image 6C is created by the function of the third stereoscopic image creation means 7C.

The three types of stereoscopic images 6 (first stereoscopic image 6A, second stereoscopic image 6B, third stereoscopic image 60) may be simultaneously displayed side by side on the display device 9. Alternatively, as shown in FIG. 1 and FIG. 2, any one stereoscopic image 6 may be selected by an operation of the customer using the function of a selection button 10 disposed upstream of the output means 8, and may be displayed on the display device 9. By successively switching the target to be displayed on the single display device 9 among the first stereoscopic image 6A, the second stereoscopic image 6B, and the third stereoscopic image 6C, the customer can quickly grasp differences in these stereoscopic images. Thus, the customer can quickly determine points to be corrected in the stereoscopic image 6.

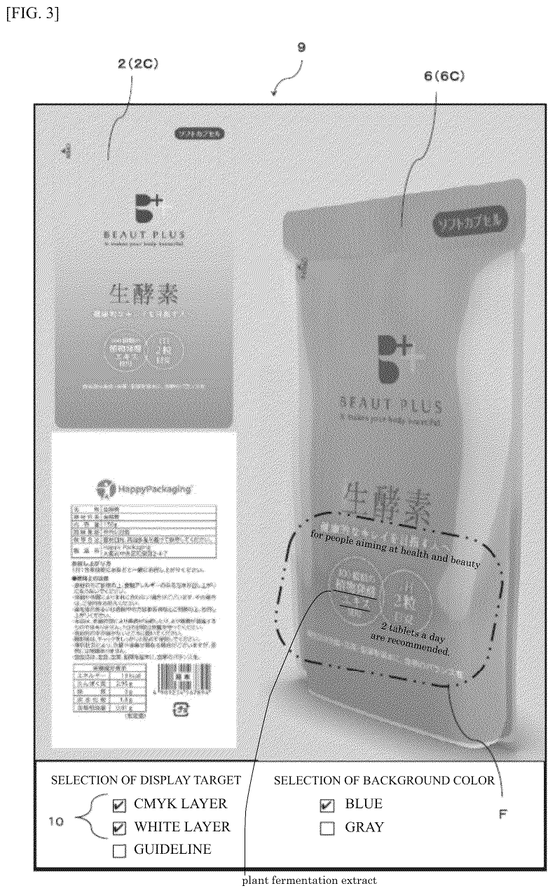

FIG. 3 to FIG. 8 each show the screen of the display device 9 on which data from the output means 8 are displayed. On the left side of the screen, the two-dimensional image data 2 indicating designs on the front and rear sides of a retort pouch being a commodity is displayed. On the right side of the screen, the stereoscopic image 6 in which the two-dimensional image data 2 on the left side is printed on the retort pouch being a commodity is displayed. In addition, in FIG. 3 to FIG. 8, a selection button 10 is displayed on a lower part of the screen, and allows selection of the two-dimensional image data 2. In FIG. 3 to FIG. 8, a topmost check box, of the selection button 10, is for selecting display of the second two-dimensional image data 2B (CMYK layer) in a plurality of colors, and a second check box from the top is for selecting display of the first two-dimensional image data 2A (white layer) in a single color.

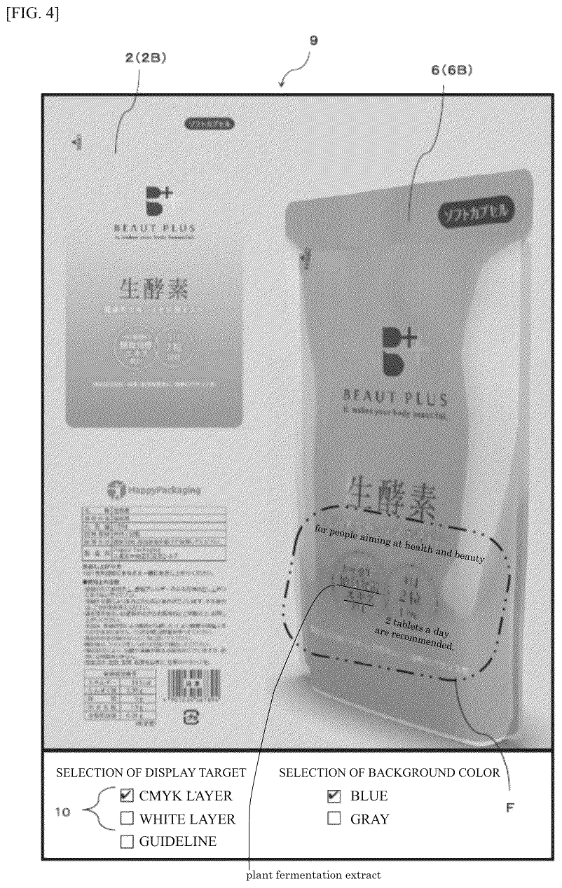

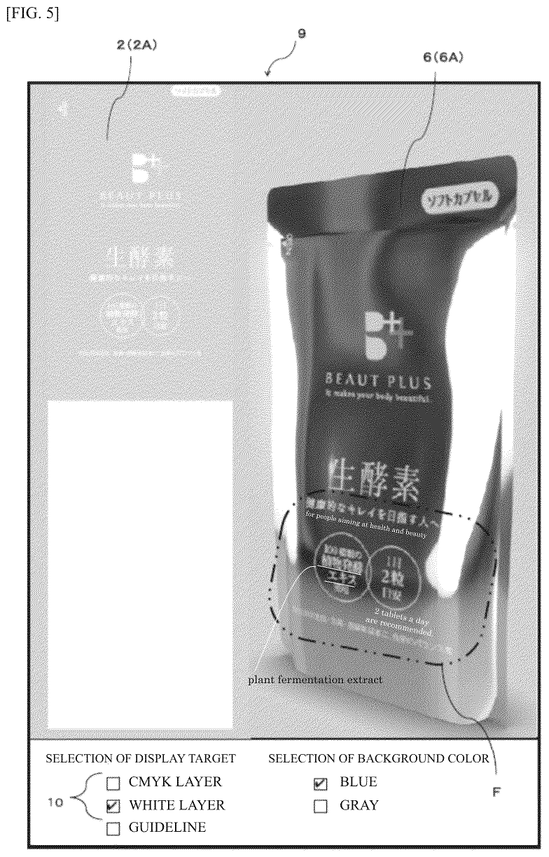

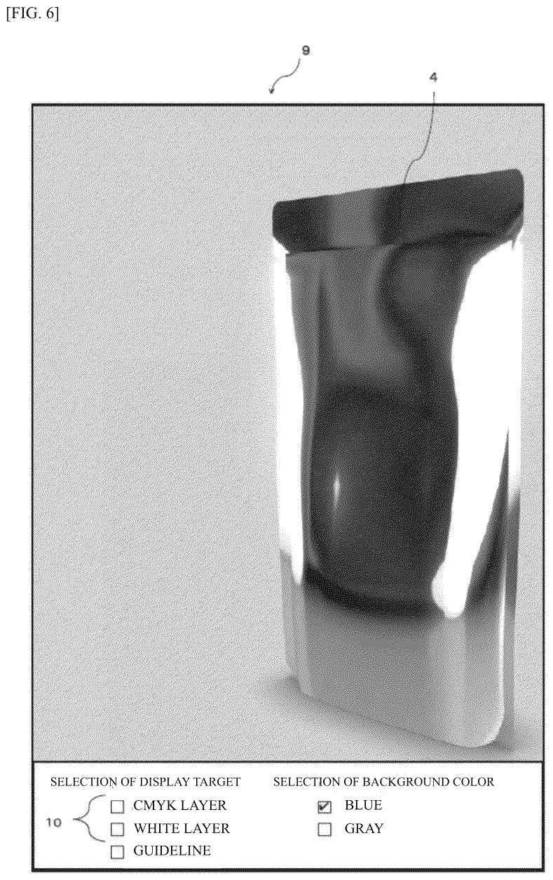

FIG. 3 to FIG. 6 correspond to the screens in which the check boxes for the CMYK layer and the white layer are switched by being checked/unchecked. FIG. 3 shows a case where both the CMYK layer and the white layer are checked, FIG. 4 shows a case where only the CMYK layer is checked, FIG. 5 shows a case where only the white layer is checked, and FIG. 6 shows a case where both the CMYK layer and the white layer are unchecked. FIG. 6 shows a state where only the three dimensional shape data 4 (stereoscopic image on which the two-dimensional image data 2 is not superimposed) of the container (retort pouch) is displayed on the right side of the screen because the stereoscopic image creation means 7 is not operated.

In particular, with reference to areas denoted by “F” on the lower right parts of the screens shown in FIG. 3 to FIG. 5, the letters of “for people aiming at health and beauty”, “plant fermentation extract”, and “2 tablets a day are recommended” are clearly seen in the third stereoscopic image 6C in FIG. 3 in which the CMYK layer and the white layer are superimposed with each other, but these letters become darker and are difficult to read in the second stereoscopic image 6B in FIG. 4 in which the white layer is absent. If the customer who sees such a screen wants to make these letters moderately easy to read but considers that the design of the entire retort pouch may be impaired by making the white layer completely white, the customer can correct the brightness of the first two-dimensional image data 2A constituting the white layer, and can intuitively set an adequate correction width by comparing FIG. 3 to FIG. 5. Therefore, the customer can obtain a desired third stereoscopic image 6C without performing several times of proofing.

In the image display system according to the embodiment of the present invention, the stereoscopic image creation means 7 is preferably a program based on the premise that the container to be displayed is a flexible packaging container. The reason is because the program allows the customer to easily grasp the actual shape, color, and reflection of the stereoscopic image 6, even though the flexible packaging container has many curved surfaces in the shape of its surface.

The image display system according to the embodiment of the present invention preferably includes gloss information imparting means (not shown) that imparts, to the three-dimensional shape data 4, information indicating that the container itself has a glossy surface. The reason is because such a gloss has an influence on the apparent colors of the first stereoscopic image 6A to the third stereoscopic image 6C. The gloss information imparting means is preferably programmed upstream of the stereoscopic image creation means 7.

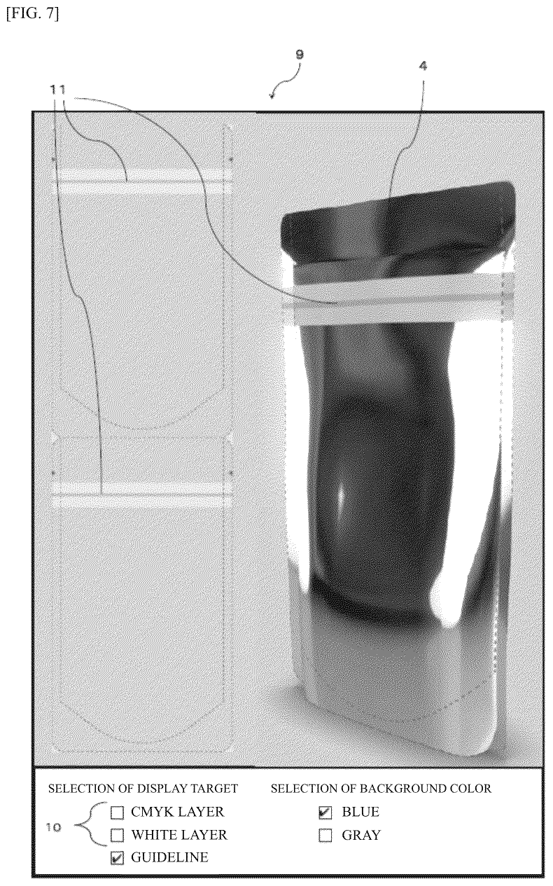

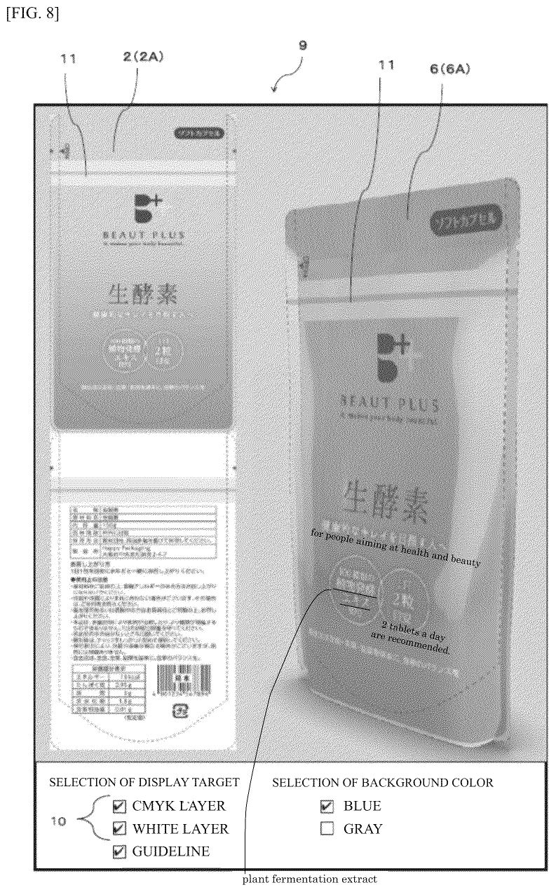

As shown in FIG. 7 and FIG. 8, it is preferable that a mark 11 indicating the position of a fastener of the container is outputted to the display device 9. This allows the degree of interference between the fastener that is a component necessary for ensuring the function of the container, and the two-dimensional image data 2 to be easily confirmed. Such a function is realized by, for example, the function of the output means 8. Whether or not the fastener 11 is displayed may be selected by using a check box as shown in FIG. 7 and FIG. 8.

It is preferable that the stereoscopic image creation means 7 further includes a fourth stereoscopic image creation means (not shown) that creates a fourth stereoscopic image by superimposing gloss adjustment data on the third stereoscopic image 6C. For example, the fourth stereoscopic image creation means corresponds to a simulation in which a colored container is further coated with a resin layer (varnish layer) having a luster effect on its surface. It is preferable that whether or not to superimpose the gloss adjustment data is selectable by using a check box (not shown) on the display device 9.

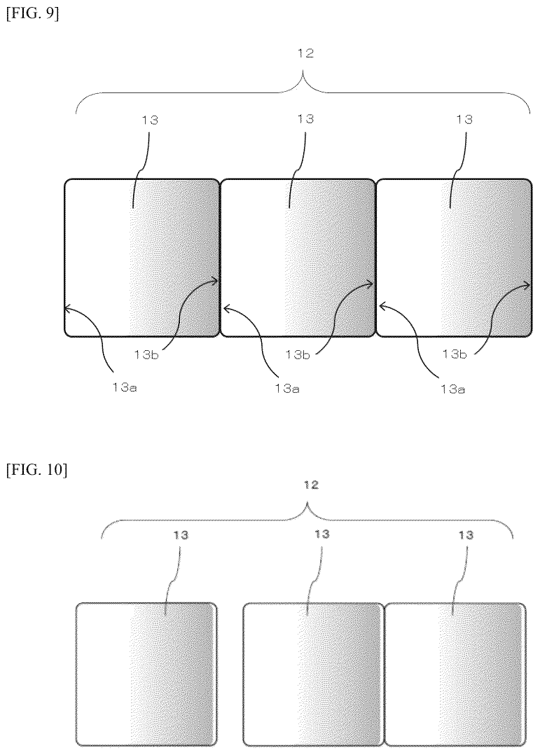

FIG. 9 is a plan view showing a sheet-like material 12 disposed on the surface of the container. In the embodiment of the present invention, the two-dimensional image data 2 is preferably data to be printed on a sheet-like material 12 disposed on the surface of the container, and the sheet-like material 12 has a plurality of first print regions 13 arranged in parallel. One first print region 13 corresponds to one container, and has a first side 13a and a second side 13b opposing the first side 13a. In FIG. 9, the two-dimensional image data 2 in a gradation state, in which the color tone gradually darkens from the first side 13a side toward the second side 13b side, is disposed. After the two-dimensional image data 2 is printed on the sheet-like material 12, the sheet-like material is cut for each first print region 13 and attached to each container. The two-dimensional image data 2 is desired to be printed on the sheet-like material 12 without misregistration as shown in FIG. 9, but the printing may sometimes be slightly shifted to the left with respect to the sheet-like material 12 as shown in FIG. 10. This phenomenon is unavoidable to some extent as long as printing technology is used.

In the first print region 13, if a difference in color between the two-dimensional image data in a first edge area (not shown) including the first side 13a and the two-dimensional image data in a second edge area (not shown) including the second side 13b is small, the appearance of the container is not inferior in many cases even if there is some positional deviation. Therefore, when at least one of the following (1) to (3) is satisfied, since the positional deviation becomes conspicuous, it is preferable to issue a predetermined warning. It is preferable that the width of the first edge area and the width of the second edge area are not uniformly determined but are set as appropriate in consideration of the whole area of first print region 13.
(1) A difference in brightness between the two-dimensional image data 2 in the first edge area including the first side 13a and the two-dimensional image data 2 in the second edge area including the second side 13b is a predetermined value or more.
(2) A difference in chromaticity between the two-dimensional image data 2 in the first edge area including the first side 13a and the two-dimensional image data 2 in the second edge area including the second side 13b is a predetermined value or more.
(3) A difference in chroma saturation between the two-dimensional image data 2 in the first edge area including the first side 13a and the two-dimensional image data 2 in the second edge area including the second side 13b is a predetermined value or more.

In the above (1), in order to simply compare the brightness of the two-dimensional image data 2 in the first edge area with the brightness of the two-dimensional image data 2 in the second edge area, it is preferable to use an average value in the first edge area and an average value in the second edge area. Also, for the chromaticity in the above (2) and the chroma saturation in the above (3), it is preferable to use average values as well.

When the container is a retort pouch as shown in FIG. 3 to FIG. 8, the front side and the rear side of the retort pouch are simultaneously printed by using two adjacent regions on the sheet-like material in many cases.

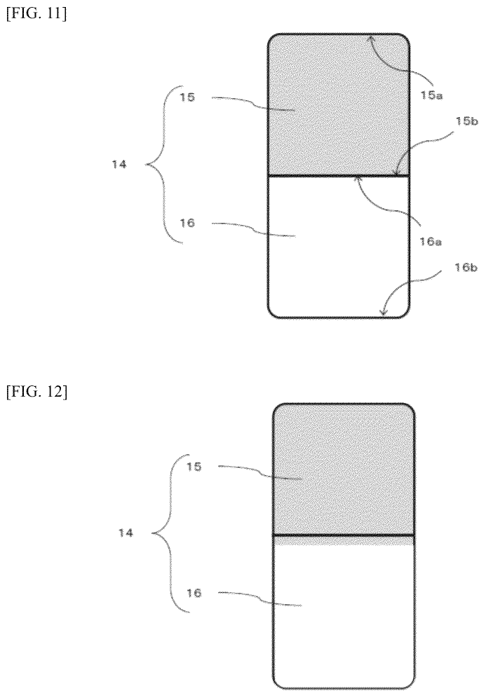

FIG. 11 is a plan view showing a sheet-like material 14 disposed on the front surface and the rear surface of a container. In FIG. 11, the sheet-like material 14 includes: a rectangular first print region 15 having a first side 15a and a second side 15b opposing the first side 15a; and a rectangular second print region 16 having a third side 16a adjacent to the second side 15b of the first print region 15, and a fourth side 16b opposing the third side 16a. As in the case of FIG. 10, printing may sometimes be slightly shifted in the plan surface of the drawing with respect to the sheet like material 14 as shown in FIG. 12.

Therefore, when at least one of the following (1) to (3) is satisfied, since the positional deviation becomes conspicuous, it is preferable to issue a predetermined warning. It is preferable that the width of the second edge area and the width of the third edge area are not uniformly determined but are set as appropriate in consideration of the whole area of the first print region 15 and the second print region 16.
(1) A difference in brightness between the two-dimensional image data in the second edge area including the second side 15b of the first print region 15 and the two-dimensional image data in the third edge area including the third side 16a of the second print region 16 is a predetermined value or more.
(2) A difference in chromaticity between the two-dimensional image data in the second edge area including the second side 15b of the first print region 15 and the two-dimensional image data in the third edge area including the third side 16a of the second print region 16 is a predetermined value or more.
(3) A difference in chroma saturation between the two-dimensional image data in the second edge area including the second side 15b of the first print region 15 and the two-dimensional image data in the third edge area including the third side 16a of the second print region 16 is a predetermined value or more.

In the above (1), in order to simply compare the brightness of the two-dimensional image data 2 in the second edge area with the brightness of the two-dimensional image data 2 in the third edge area, it is preferable to use an average value in the second edge area and an average value in the third edge area. Also, for the chromaticity in the above (2) and the chroma saturation in the above (3), it is preferable to use average values as well.

In the embodiment of the present invention, it is preferable that the container data storage means 5 stores a plurality of three-dimensional shape data 4, and the image display system further includes container selection means that selects three-dimensional shape data 4 of a container requested by the customer from among the plurality of three-dimensional shape data 4.

In the embodiment of the present invention, it is preferable that the customer is capable of settling purchase of a container, based on the first two-dimensional image data 2A and the second two-dimensional image data 2B having been subjected to proofing by the customer and determined.

This application claims the benefit of the priority date of Japanese patent application No. 2022-032067 filed on Mar. 2, 2022. All of the contents of the Japanese patent application No. 2022-032067 filed on Mar. 2, 2022 are incorporated by reference herein.

### REFERENCE SIGNS LIST

1: Image display system
2: Two-dimensional image data
3: Customer image storage means
4: Three-dimensional shape data of a container
5: Container data storage means
6: Stereoscopic image
6A: First stereoscopic image
6B: Second stereoscopic image
6C: Third stereoscopic image
7: Stereoscopic image creation means
7A: First stereoscopic image creation means
7B: Second stereoscopic image creation means
7C: Third stereoscopic image creation means
8: Output means
9: Display device
10: Selection button
11: Mark
12: Sheet-like material
13: First print region
13a: First side
13b: Second side
14: Sheet-like material
15: First print region
15a: First side
15b: Second side
16: Second print region
16a: Third side
16b: Fourth side

1. An image display system comprising:
customer image storage means that stores two-dimensional image data provided by a customer;
container data storage means that stores three-dimensional shape data of a container provided by a vendor;
stereoscopic image creation means that creates a stereoscopic image by superimposing the two-dimensional image data on the three-dimensional shape data; and
output means that outputs the stereoscopic image to a display device, wherein
the two-dimensional image data includes first two-dimensional image data rendered in a single color, and second two-dimensional image data rendered in a plurality of colors, and
the stereoscopic image creation means includes
(A) first stereoscopic image creation means that creates a first stereoscopic image by superimposing the first two-dimensional image data on the three-dimensional shape data,
(B) second stereoscopic image creation means that creates a second stereoscopic image by superimposing the second two-dimensional image data on the three-dimensional shape data, and
(C) third stereoscopic image creation means that creates a third stereoscopic image by superimposing the second two-dimensional image data on the first stereoscopic image.

2. The image display system according to claim 1, wherein
the output means outputs, to the display device, a selection button that allows selection of an image to be displayed on the display device from among the first to third stereoscopic images.

3. The image display system according to claim 1, wherein
the output means is capable of displaying a stereoscopic image in which the two-dimensional image data is not superimposed on three-dimensional shape data of a selected container.

4. The image display system according to claim 1, wherein
the container is a flexible packaging container.

5. The image display system according to claim 1, further comprising gloss information imparting means that imparts, to the three-dimensional shape data, information indicating that the container has a glossy surface.

6. The image display system according to claim 1, wherein
the first two-dimensional image data is rendered in a single white color.

7. The image display system according to claim 1, wherein
the output means is capable of outputting, to the image, a mark indicating a position of a fastener of the container.

8. The image display system according to claim 1, wherein
the stereoscopic image creation means further includes fourth stereoscopic image creation means that creates a fourth stereoscopic image by superimposing gloss adjustment data on the third stereoscopic image.

9. The image display system according to claim 1, wherein
the two-dimensional image data is data to be printed on a sheet-like material disposed on a surface of the container, the sheet-like material has a first print region having a first side and a second side opposing the first side, and a predetermined warning is issued when at least one of conditions (1) to (3) below is satisfied:
(1) a difference in brightness between the two-dimensional image data in a first edge area including the first side and the two-dimensional image data in a second edge area including the second side is a predetermined value or more;
(2) a difference in chromaticity between the two-dimensional image data in the first edge area including the first side and the two-dimensional image data in the second edge area including the second side is a predetermined value or more; and
(3) a difference in chroma saturation between the two-dimensional image data in the first edge area including the first side and the two-dimensional image data in the second edge area including the second side is a predetermined value or more.

10. The image display system according to claim 1, wherein
the two-dimensional image data is data to be printed on a sheet-like material disposed on a surface of the container, the sheet-like material has a first print region having a first side and a second side opposing the first side, and a second print region having a third side adjacent to the second side of the first print region and a fourth side opposing the third side, and a predetermined warning is issued when at least one of conditions (1) to (3) below is satisfied:
(1) a difference in brightness between the two-dimensional image data in a second edge area including the second side of the first print region and the two-dimensional image data in a third edge area including the third side of the second print region is a predetermined value or more;
(2) a difference in chromaticity between the two-dimensional image data in the second edge area including the second side of the first print region and the two-dimensional image data in the third edge area including the third side of the second print region is a predetermined value or more; and
(3) a difference in chroma saturation between the two-dimensional image data in the second edge area including the second side of the first print region and the two-dimensional image data in the third edge area including the third side of the second print region is a predetermined value or more.

11. The image display system according to claim 1, wherein
the container data storage means stores a plurality of three-dimensional shape data, and
the image display system further comprises container selection means that selects three-dimensional shape data of a container requested by the customer from among the plurality of three-dimensional shape data.

12. The image display system according to claim 1, wherein
the customer is capable of settling purchase of a container, based on the first two-dimensional image data and the second two-dimensional image data having been determined.
